(19) United States
(12) Patent Application Publication
(10) Pub. No.: US 2019/0267822 A1
(43) Pub. Date: Aug. 29, 2019

(54) Charging Station Foundation and Charging Station

(71) Applicants: Jürgen Waffner, Essen (DE); Stephan Voit, Essen (DE)

(72) Inventors: Jürgen Waffner, Essen (DE); Stephan Voit, Essen (DE)

(73) Assignee: innogy SE, Essen (DE)

(21) Appl. No.: 16/409,547

(22) Filed: May 10, 2019

Related U.S. Application Data
(63) Continuation of application No. PCT/EP2017/064919, filed on Jun. 19, 2017.

(30) Foreign Application Priority Data
Nov. 11, 2016 (DE) 10 2016 121 629.1

(51) Int. Cl. H02J 7/00; H05K 7/20; E02D 27/46; E02D 27/01; B60L 53/302

(52) U.S. Cl. CPC H02J 7/0042; H05K 7/209; E02D 2600/00; E02D 27/016; B60L 53/302; E02D 27/46

(57) ABSTRACT

Charging station foundation having an inlet for a power supply line and a recess for receiving charging electronics, the inlet being guided from an outer wall of the foundation to an inner wall of the recess. In order to increase the reliability of charging infrastructure, it is provided that charging electronics at least comprising a circuit breaker and a charging controller protected according to protection class IPxy with x>=6 and y>=6, preferably y>=8 according to DIN EN 60529, are arranged in the recess.

### CROSS-REFERENCE TO RELATED PATENT APPLICATIONS

This patent application is a continuation of PCT/EP2017/064919, filed Jun. 19, 2017, which claims priority to German Application No. 10 2016 121 629.1, filed Nov. 11, 2016, the entire teachings and disclosure of which are incorporated herein by reference thereto.

### FIELD

The subject-matter concerns a charging station foundation and a charging station.

### BACKGROUND

The development of a functioning charging infrastructure for electric vehicles is of crucial importance for the acceptance of electric mobility. However, the operators of charging infrastructure are faced with the problem that this must always be made available as error-free as possible in order to achieve customer acceptance. This is particularly challenging in view of the fact that charging infrastructure, especially charging stations, are constantly exposed to changing environmental conditions. However, especially in the field of charging electronics, in particular the charging controller and fuse switches, high temperature fluctuations are undesirable due to increased wear and the risk of malfunction.

A considerable amount of computing power is also required within the charging electronics, in particular the charging controller, not least because of the encrypted communication with the electric vehicle to be charged and/or with a billing centre. The required computing power generates heat loss, which must be dissipated to prevent damage to the electronics. However, dissipating thermal loss is particularly difficult when a charging station is exposed to the blazing sun without protection. This may result in temperatures of 70° C. and more being reached inside the charging station. However, such high temperatures lead to failures of the charging electronics, which, as explained above, are not desirable.

The inventors have recognized that considerably lesser temperature fluctuations in the ground can be used to provide stable operation of the charging infrastructure, in particular the charging station, by particularly simple means. The subject-matter was based on the object of increasing the reliability of charging infrastructure.

### BRIEF SUMMARY

This object is solved by a charging station foundation according to the present disclosure. It has been recognized that components of the charging infrastructure, in particular the charging electronics and in particular the charging controller, have highly temperature-dependent characteristic curves and that a permitted temperature range must be maintained for safe operation. It has also been recognized that during continuous operation, temperatures can occur inside the housings of charging stations that are outside the permitted temperature range of the components used. Temperatures of over 70° C. in particular can occur inside a charging station, which can lead to failures or even damage of the charging infrastructure.

By moving the charging electronics into the interior of the charging station foundation, the temperature in the charging electronics is exposed to lower fluctuations. In the installed state, the temperature fluctuation in the foundation is usually considerably lesser than in a housing arranged above the ground level. This low temperature fluctuation is used, according to the invention to ensure more reliable operation of the charging electronics.

However, in order to be able to safely operate the charging electronics, in particular at least a circuit breaker and a charging controller below the floor level when installed, it is necessary that they are protected according to protection class IPxy with x>=6 and y>=6, preferably y>=8 in accordance with DIN EN 60529. This water-protected arrangement of the charging electronics within the recess of the charging station foundation ensures trouble-free operation even during brief flooding. The charging station does not have to be disconnected from the mains even in heavy rain and brief flooding, as the proposed protection class ensures fault-free operation of the charging electronics.

The charging station foundation is preferably a prefabricated, cast component, especially of concrete. This has an inlet for a power supply line and a recess for receiving the charging electronics.

The recess is an interior space in the foundation, which is preferably adapted to the size of the charging electronics. Preferably, the recess forms a housing for the charging electronics within the foundation.

Via the inlet, the energy supply can be routed from the outer wall of the foundation to the recess. The inlet serves, for example, to accommodate an underground cable which is connected to an energy supply network, especially a local network, especially a low-voltage network with a voltage level of 0.4 kV. A connection to a medium voltage network with a voltage level of up to 10 kV is also possible.

In order to enable the foundation with the charging electronics to be embedded in the floor and thus to ensure that the temperature of the charging electronics is as constant as possible, the charging electronics are water-protected in the recess. It has been found that the protection of the charging electronics according to protection class IPxy with x>=6 and y>=6 is sufficient. For continuous operation, even in case of flooding, y>=8 is preferred.

To prevent layer groundwater from penetrating the recess, the foundation is preferably circumferentially watertight, except for an outlet in the recess area for a charging cable. The inlet is preferably watertight, so that the power supply line is watertight through the inlet. A pressure tightness for a water pressure of maximum 0.5 bar, preferably maximum 1 bar, in particular up to a water pressure of 5 bar is preferred.

According to an embodiment, it is proposed that the recess is enclosed by the foundation on five sides by four walls and a floor. The foundation is preferably cast in one piece and encloses the recess. In the area of a ceiling, the receptacle has an outward-facing connection (opening). The opening preferably has a clear opening that is sufficient to accommodate the charging electronics.

It has been found that the charging station foundation should have an installation depth of 80 cm to 1 m if possible. It has also been found that the edge length of the foundation should be between 60 and 80 cm. However, in order to provide a visually appealing image of the top surface, the edge length of the foundation should be smaller in the surface area. For this reason, it is proposed that the opening be located in the area of a dome protruding from the ceiling of the foundation. The foundation is preferably stepped with a main body and a dome, whereby the dome is arranged at least partially above the ground level when the foundation is installed. The dome is preferably cast in one piece together with the foundation. The dome and foundation are preferably cast from waterproof concrete. By placing the dome partially above the floor level when installed, the risk of water ingress into the recess can be reduced. The dome preferably has the opening only in the area of its front side, so that surface water cannot flow into the opening at first if the dome is at least partially above ground level.

The edge length of the dome preferably corresponds at most to the edge length of the charging station arranged on it, so that neither the foundation nor the dome is visible when the charging station is fixed.

To fasten the charging station to the foundation, the dome has, at its front face, connection consoles for a charging station. The front face connection consoles can be in the form of cast threaded sleeves or threaded bolts embedded in the foundation or dome. During assembly, the charging station can be easily screwed into the threaded sleeve with a screw or fastened to the threaded bolt with a nut.

According to an embodiment, it is proposed that the dome has a smaller circumference than the circumference of the ceiling area on which the dome is arranged.

As already mentioned, the foundation serves for embedding into the ground and for the operation of the charging electronics therein. Therefore, it is proposed that in an installation condition the inlet and at least parts of the recess are below a ground level. Preferably only the dome protrudes in parts above the ground level.

According to an embodiment, it is proposed that the charging electronics arranged in the recess are set up for the complete handling of a charging process. The charging controller has a corresponding logic for handling a charging process in order to determine whether an electric vehicle is ready for charging. For this purpose, signals on the charging cable between the electric vehicle and the charging controller are exchanged using pulse width modulation, for example. The charging controller can also release a charging current or interrupt a charging current. Finally, the charge controller can be used to determine whether a charging cable is correctly connected to an electric vehicle. This can be detected, for example, via a so-called plug-present signal. Via a pilot line arranged in the charging cable, charge-specific signals can be exchanged between the charging controller and the electric vehicle. These functions can be combined in the charging electronics, which are arranged in the recess preferably in the installed state below the ground level.

A particularly safe arrangement of the charging electronics in the recess is given if the charging electronics are cast in the recess. For this purpose, the charging electronics can be completely encapsulated in the recess using a synthetic resin, for example.

Watertightness can also be achieved by encapsulating the charging electronics in a housing. The housing has the protection class as defined above. The housing is also located in the recess.

Especially when the charging electronics are encapsulated in a housing or encapsulated in a synthetic resin, convection cooling is hindered. A heat sink may be provided to improve cooling. The heat sink is preferably metallic. The heat sink can extend from the inside of the recess to at least one outer wall of the foundation. Preferably the heat sink protrudes beyond the outer wall of the foundation into the ground. This enables particularly good cooling and a constant temperature inside the recess.

According to an embodiment, it is proposed that the heat sink covers a bottom and/or an inner wall of the recess at least partially preferably as a metallic plate.

To prevent layered groundwater from entering the interior of the foundation via the heat sink, it is suggested that the heat sink is arranged watertight between the recess and an outer wall of the foundation.

A particularly good temperature regulation is achieved when the base material of the foundation is equipped with a phase change material. Such a phase change material has the property of being able to absorb or release a disproportionate amount of energy at the moment of the phase change. This makes it possible to counteract strong temperature fluctuations through the phase change.

Another aspect is a charging station with a previously described charging station foundation. The charging station has a housing which is attached to the charging station foundation, especially on the front face of the dome. For the charging process, the charging station is connected to the charging electronics inside the recess. The charging electronics in the recess are thus used for the charging process. The charging station therefore does not carry any charging electronics, but merely serves to accommodate the charging cable of the electric vehicle or to provide a charging cable for an electric vehicle.

Preferably, a charging cable led out of the opening in the housing is led directly to a charging socket or charging plug. The housing therefore only has a design character and the entire charging electronics are arranged in the foundation.

### BRIEF DESCRIPTION OF THE DRAWING

In the following, the subject-matter is explained in more detail using a drawing showing embodiments. In drawing show:

FIG. 1 shows a schematic view of a charging station foundation;

FIG. 2 shows a schematic cross-sectional view of a charging station foundation with charging electronics; and

FIG. 3 shows a schematic view of a charging station with a charging station foundation.

### DETAILED DESCRIPTION

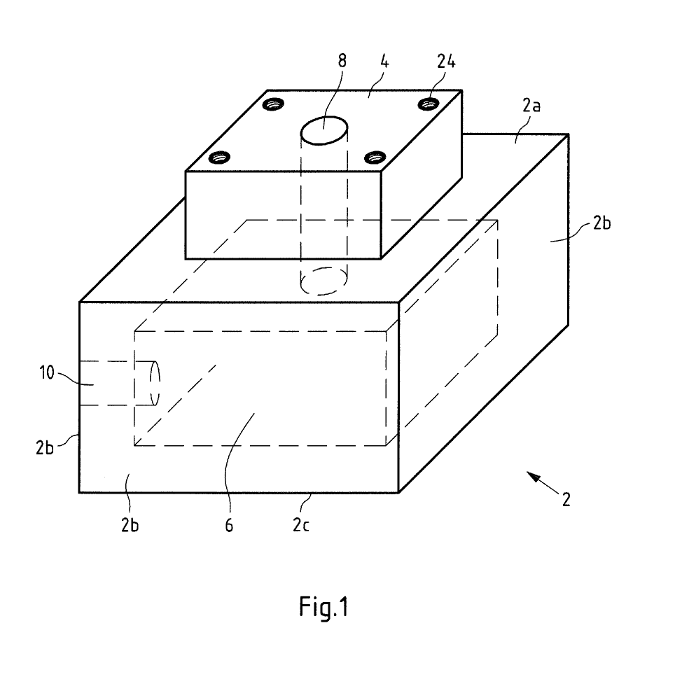

FIG. 1 shows a charging station foundation 2. A dome 4 is preferably arranged in one piece on foundation 2 in the area of a ceiling surface 2a. The foundation has four side walls 2b and a floor 2c. A recess 6 is provided in the foundation itself, which is enclosed by the side surfaces 2b and the base 2c. In the area of the ceiling surface 2a, the recess 6 extends outwards via an opening 8.

In addition, an inlet 10 is provided through which a watertight power supply cable can be led into the inside of the foundation in the recess 6.

The recess 6 accommodates a charging electronics 12 secured against water.

It can be seen that the circumference of the dome 4 is smaller than the circumference of the ceiling area 2a. Furthermore, the dome 4 protrudes from the ceiling surface 2a. The opening 8 preferably has a clear width to accommodate a charging electronics 12.

It can also be seen that 4 threaded sleeves 24 are arranged on the front side of the dome, via which the charging station 30 can be screwed to the foundation 2.

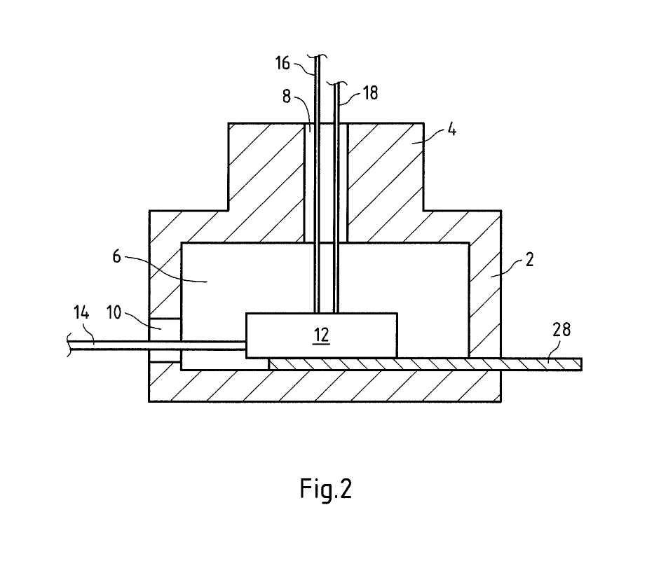

FIG. 2 shows a schematic cross-sectional view through a foundation 2. It can be seen that the charging electronics 12 are encapsulated in a housing. The housing is preferably designed according to IP protection class IP66, IP67 or IP68. Higher protection classes are also possible. The power supply line 14 is led through inlet 10 into the interior of foundation 2, thus into recess 6. The passage through inlet 10 is preferably watertight. The power supply cable 14 is preferably led watertight into the housing of the charging electronics 12. At least one charging cable 16 is led out of the charging electronics watertight. In addition, an antenna 18 can also be led out of the housing 12 watertight. Both the charging cable 16 and the antenna 18 are led out of the foundation 2 via the opening 8.

The charging electronics 12 accommodates at least a charging controller and a circuit breaker, preferably a contactor and a fault current switch, in particular a type 3 fault current switch. The charging electronics 12, in particular the charging controller, handles all communication with the electric vehicle as well as communication with a billing centre if necessary, preferably wirelessly using the antenna 18. Communication with the electric vehicle is preferably via the charging cable 16.

FIG. 2 also shows that the dome 4 is formed in one piece with the foundation 2. A phase change material is preferably incorporated in the material of the dome 4 and the foundation 2 in order to enable increased temperature stability within the recess 6.

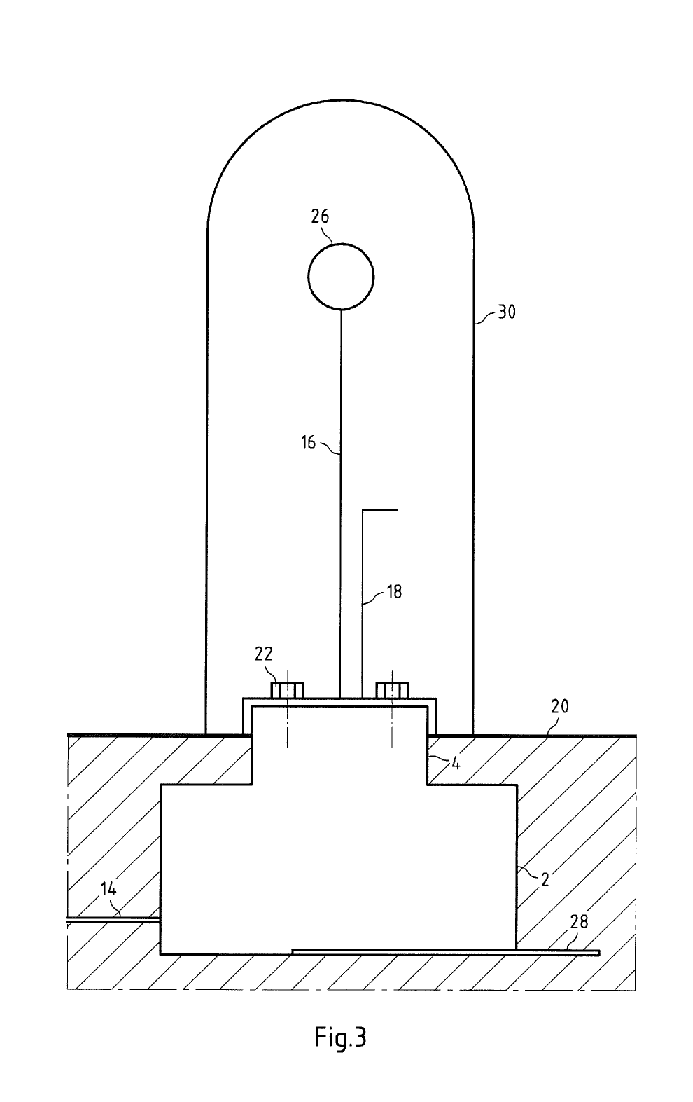

In the installation position, foundation 2 is preferably below ground level 20, as shown in FIG. 3. FIG. 3 shows that foundation 2 is completely below ground level 20 and only part of dome 4 protrudes from the ground. It can be seen that charging station 2 is screwed with connecting means 22, in particular screws, to the sleeves 24 arranged on the front face of dome 4. The charging cable 16, which is directly connected to a charging socket 26, is led out of dome 4. The charging cable 16 can be connected to a charging cable durably attached to the charging station 2. The antenna 18 is guided inside charging station 2 and, by being guided out of ground level 20, enables communication with a remote control centre, for example via a wide area network.

The fact that foundation 2 is embedded in the ground ensures that an optimized temperature curve is achieved during operation; in particular, it ensures that the charging electronics can always be kept below a maximum temperature limit, e.g. 70° C. Cooling is optimised, for example, by the fact that, as shown in FIG. 2, a heat sink 28, e.g. in the form of a metallic plate, is arranged at the bottom of the receptacle 6. The heat sink 28 is guided from the inside of the recess 26 to the outside and beyond. The heat sink 28 is in the installation position in the ground and enables a good cooling of the interior of the recess 6. Preferably the housing of the charging electronics 12 is fastened directly to the heat sink 28 or placed on it.

All references, including publications, patent applications, and patents cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A charging station foundation, comprising:
an inlet for a power supply line, and
a recess for receiving charging electronics,
wherein the inlet is guided from an outer wall of the foundation to an inner wall of the recess,
wherein the charging electronics comprise at least one power circuit breaker and a charging controller protected by a casing or cast in the recess in accordance with protection class IPxy with x>=6 and y>=6 in accordance with DIN EN 60529 is arranged in the recess.

2. The charging station foundation according to claim 1, wherein the power supply line is led watertight through the inlet.

3. The charging station foundation according to claim 1, wherein the recess is enclosed on five sides by the foundation with four walls and a floor and has an opening pointing outwards on its ceiling.

4. The charging station foundation according to claim 3, wherein the opening is arranged in the region of a dome projecting from the ceiling of the foundation, the dome being arranged at least partially above the ground level in the installed state of the foundation.

5. The charging station foundation according to claim 4, wherein the dome has connection consoles for a charging station at its end face.

6. The charging station foundation according to claim 4, wherein the dome has a smaller circumference than the ceiling surface on which the dome is arranged.

7. The charging station foundation according to claim 1, wherein in an installed state, the inlet and at least parts of the recess are below a ground level.

8. The charging station foundation according to claim 1, wherein the charging electronics arranged in the recess are set up for the complete execution of a charging process, comprising at least the detection of a charging readiness, the release of a charging current, the detection of an unconnected charging cable and the interruption of the charging current.

9. The charging station foundation according to claim 1, wherein a heat sink is arranged to project from the interior of the recess to at least one outer wall.

10. The charging station foundation according to claim 9, wherein the heat sink at least partially covers a base and/or an inner wall of the recess.

11. The charging station foundation according to claim 9, wherein the heat sink is arranged in a watertight manner between the recess and an outer wall of the foundation.

12. The charging station foundation according to claim 1, wherein a carrier material of the foundation is equipped with a phase change material.

13. A charging station, comprising:
the charging station foundation according to claim 1; and
a housing fastened to the charging station foundation;
wherein the charging station uses the charging electronics arranged in the recess for a charging process.

14. The charging station according to claim 13, wherein a charging cable led out of an opening in the housing is led directly to a charging socket or charging plug.

15. The charging station foundation according to claim 1, wherein y>=8.

16. The charging station foundation according to claim 9, wherein the heat sink is metallic.

17. The charging station foundation according to claim 9, wherein the heat sink projects beyond an outer wall of the foundation.

18. The charging station foundation according to claim 10, wherein the heat sink is a metallic plate.

19. The charging station foundation according to claim 12, wherein the carrier material comprises concrete.
